(19) United States
(12) Patent Application Publication
(10) Pub. No.: US 2023/0416095 A1
(43) Pub. Date: Dec. 28, 2023

(54) NANOMATERIAL MANUFACTURING METHODS

(71) Applicant: CVD Equipment Corporation, Central Islip, NY (US)

(72) Inventors: Maxim S. Shatalov, Mt. Sinai, NY (US); Samuel J. Wright, Bellport, NY (US); Mikhail Gaevski, Middle Island, NY (US)

(21) Appl. No.: 18/211,608

(22) Filed: Jun. 20, 2023

Related U.S. Application Data
(60) Provisional application No. 63/355,200, filed on Jun. 24, 2022.

(51) Int. Cl. C01B 32/162; H01M 4/36; H01M 4/38; H01M 4/587; C01B 32/168; C23C 16/04; C23C 16/26; C23C 16/24; C23C 16/56

(52) U.S. Cl. CPC C01B 32/162; H01M 4/366; H01M 4/386; H01M 4/587; C01B 32/168; C23C 16/045; C23C 16/26; C23C 16/24; C23C 16/56; C01B 2202/22; C01B 2202/08; C01P 2004/16; C01P 2004/80

(57) ABSTRACT

Methods permit the growth of two or more nanomaterials in a common process chamber in the same batch run, either simultaneously or sequentially, using one or a combination of CVD, CVI, or other techniques. The methods described can be beneficial for forming nanosilicon-containing nanocarbon structures suitable for use as a battery anode material.

### CROSS-REFERENCE TO RELATED APPLICATION

This application claims the benefit of, and priority to, U.S. Provisional Patent Application No. 63/355,200 filed on Jun. 24, 2022, the entire contents of which are hereby incorporated herein by reference.

### TECHNICAL FIELD

This disclosure is directed in general to methods for growing nanomaterials.

### BACKGROUND

Nanomaterials (e.g., silicon nanowires (SiNWs) or carbon nanotubes (CNTs)) can be produced, for example, in chemical vapor deposition (CVD) horizontal tube reactors on catalytic substrates that can be either porous (e.g., mesh) or non-porous (e.g., Si wafer). Nanomaterials can also be produced in fluidized bed or rotary drum reactors where the nanomaterials are deposited on powder particles. In some cases, nanomaterials are deposited onto and within the voids of porous materials using a chemical vapor infiltration (CVI) technique. Some applications of nanomaterials (e.g., battery anode materials) typically contain both carbon and silicon nanostructures.

It would be desirable to grow two or more nanomaterials in a common process chamber in the same batch run, either simultaneously or sequentially, using one or a combination of CVD, CVI, or other techniques.

### SUMMARY

The present disclosure is directed to the methods for the growth of nanomaterials. In embodiments, the presently described methods permit the growth of two or more nanomaterials in a common process chamber in the same batch run, either simultaneously or sequentially, using one or a combination of CVD, CVI, or other techniques.

In embodiments, a method for growing nanomaterials in accordance with the present disclosure involves loading a catalytically active substrate into a process chamber, and introducing first treatment gases/vapors into the process chamber to make a treated substrate. Catalytic materials are then deposited on the treated substrate while it remains in the process chamber. The catalytically activated treated substrate is then exposed to second treatment gases/vapors to create a nanostructure composite.

In embodiments, optional etching and/or CVI treatments may be performed on either the treated substrate or the nanostructure composite.

In embodiments, the substrate may be a particulate, porous, or non-porous substrate.

In embodiments, the treated substrate may be vertically aligned carbon nanotube (VACNT) structures.

In embodiments, the nanostructure composite includes CNTs and SINWs.

In embodiments, the nanostructure composite is suitable for use in making a battery anode.

In other embodiments, a method for growing nanomaterials in accordance with the present disclosure involves depositing, via chemical vapor deposition (CVD), carbon nanotubes (CNTs) on a substrate having a first metal or metal oxide catalyst layer to provide a CNT-containing substrate. A second metal or metal oxide catalyst layer suitable for SiNW deposition is deposited onto the CNT-containing substrate to provide a catalytically active CNT-containing substrate. SiNW is deposited via CVD onto the catalytically active CNT-containing substrate to provide a SiNW-coated catalytically active CNT-containing substrate. The SiNW-coated catalytically active CNT-containing substrate is at least partially encapsulated via chemical vapor infiltration with carbon to provide a composite structure having substantial void space therein.

In embodiments, the method may further include etching the CNT-containing substrate prior to depositing SiNW. The etching may be chemical or plasma assisted etching. In embodiments, the method may further include etching the SiNW-coated catalytically active CNT-containing substrate prior to the encapsulating.

In yet other embodiments, a method for growing nanomaterials in accordance with the present disclosure involves depositing at least one of SiNW or CNT onto a substrate using one or more liquid catalyst precursors. The liquid catalyst precursor may be a copper catalyst for SiNW deposition, and the liquid catalyst precursor may be ferrocene (Fe(C₅H₅)₂) for CNT deposition. In embodiments, the liquid catalyst precursor may be Cu(1,1,1,5,5,5-hexafluoroacetylacetonate) (vinyltrimethyl-silane) (Cu(hfac)(tmvs)).

In yet other embodiments, a method for growing nanomaterials in accordance with the present disclosure involves positioning a substrate within a single process chamber, and depositing a metal-based or metal oxide-based catalyst layer onto the substrate while the substrate is within the process chamber. The catalyst layer may be suitable for chemical vapor deposition (CVD) of carbon nanotubes (CNTs), SiNW, or both.

In embodiments, the method may further include depositing CNTs and SiNW simultaneously or sequentially while the substrate remains within the process chamber in which the catalyst layer was deposited.

In embodiments, the oxide-based catalyst layer may include Cu, Ni, or Al.

In embodiments, depositing the catalyst layer onto the substrate may be conducted at a temperature from 500 and 900 degrees Celsius. In embodiments, depositing the catalyst layer onto the substrate may be conducted at a pressure from 0.1 Torr to 100 Torr.

In embodiments, the method may further include at least partially encapsulating, via chemical vapor infiltration, the SiNW- and CNT-containing substrate with carbon to provide a composite structure having substantial void space therein.

### BRIEF DESCRIPTION OF THE DRAWINGS

The above and other aspects, features, and advantages of the present nanomaterial growth processes will become more apparent in light of the following detailed description when taken in conjunction with the accompanying drawings in which:

FIGS. 1, 2 and 3 schematically depict nanomaterial growth systems suitable for performing one or more methods in accordance with the present disclosure; and

FIG. 4 is a flow diagram for an illustrative method in accordance with the present disclosure.

### DETAILED DESCRIPTION

The present disclosure is directed to the methods for the growth of nanomaterials. In embodiments, the presently described methods permit the growth of two or more nanomaterials in a common process chamber in the same batch run, either simultaneously or sequentially, using one or a combination of CVD, CVI, or other techniques. A variety of systems having a suitable process chamber for growing nanomaterials may be employed for performing the presently described methods.

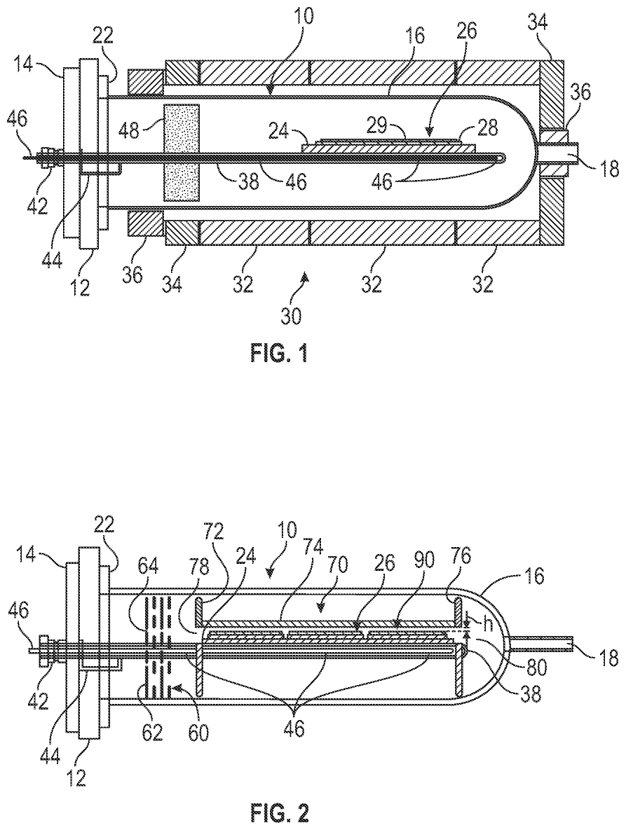

FIG. 1 shows components of an exemplary horizontal tube furnace system suitable for growing nanomaterials on a catalytically active substrate using methods in accordance with the present disclosure. The system of FIG. 1 includes a heated process chamber 10 including a gas ring 12, an end cap 14, and a process tube 16 with a narrowed-down neck exhaust gas port 18 on one side and a flange 22 on the other side. Gas entry ports and optional pressure sensors (not shown) are present in either the gas ring 12 or endcap 14. The process tube 16 is surrounded by a heater 30, for example, a clamshell oven, which can have multiple individually controllable heating zones 32, insulating the end zones 34, and optionally flexible and removable insulating means 36 between the oven end zones 34 and the process tube 16. Inside chamber 10 a substrate holder 24 is used to locate and support a catalytically active substrate 26 for nanomaterial growth. The substrate 26 includes a support 28 with a nanomaterial growth layer 29.

Substrate holder 24 is secured to a transfer arm 38 that is held and connected to the end cap 14 through a seal 42 and is additionally mechanically supported with a bracket 44. Arm 38 is hollow and holds multiple thermocouples 46 terminated at different distances from the end cap 14 that can be used to control multiple heating zones 32. A thermal shield 48 helps to reduce heat loss from the heated section of the process tube towards the gas ring 12 and end cap 14.

FIG. 2 shows another system suitable for growing nanomaterials on a catalytically active substrate using methods in accordance with the present disclosure, which is similar to the system of FIG. 1, but where the non-gas transmissive thermal shield 48 is replaced with an internal process gas preheater 60 with a tortuous gas transmission path that includes a group of intentional gas transmissive and partially thermal radiation leaking vertical baffles 62 that are spaced apart to form a spatial gap between adjacent baffles 62. Neighboring baffles 62 have offset cutouts 64 causing process gas to go through preheater 60 in a tortuous pathway while it is getting heated by the series of increasingly hotter baffles 62.

The system of FIG. 2 also includes a round-to-rectangular flow converter which may, as shown, be an H-bridge 70. H-bridge 70 includes a first bridge support (gas inlet port) 72, a horizontal top bridge 74, and a second bridge support (gas outlet port) 76. Support components 72, 74, and 76 are connected near their contact points, and support components 72 and 74 mechanically interact with support arm 38 which has suitable features for locating H-bridge 70 in a defined place along the arm 38. Gas input port 72 has an opening 78 through which process gas enters a substantially rectangular volume 90 with height h formed by the inner surface of the bridge 74, the substrate holder 24, and the inner walls of the process tube 16. The gas output port 76 has an opening 80 through which exhausted process gas escapes towards the process tube exhaust port 18 from volume 90.

In embodiments, the round-to-rectangular flow converter may (instead of the H-bridge 70 shown in FIG. 2) be a double H-bridge or simply a pair of baffles joined together by two planar walls to provide a rectangular opening for gas flow. Such alternative round-to-rectangular flow converters are described in International Application No. PCT/US22/32965 filed on Jun. 10, 2022 and entitled Controlled Nanomaterial Manufacturing, the entire disclosure of which is incorporated herein by reference.

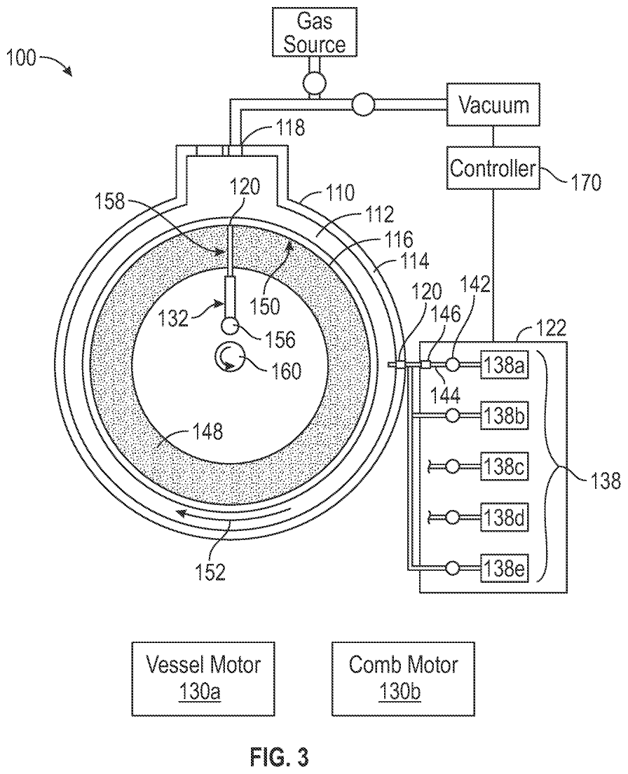

FIG. 3 shows another system suitable for growing nanomaterials using methods in accordance with the present disclosure that includes a rotary reaction vessel. Reactor system 100 includes a stationary vacuum chamber 110 that encloses a rotary treatment vessel 112. Stationary vacuum chamber 110 is enclosed by outer chamber walls 114 and rotary treatment vessel 112 is enclosed by inner chamber walls 116. Stationary vacuum chamber 110 can include one or more vacuum ports 118 for exhausting gas, e.g., treatment gases/vapors, from stationary chamber 110 and rotary treatment vessel 112. Stationary vacuum chamber 110 includes a gas inlet port 120 coupled to a chemical delivery system 122 located outside of stationary vacuum chamber 110.

Chemical delivery system 122 may include one or multiple fluid sources 138, controllable valves 142, and a fluid supply line 144. Chemical delivery system 122 injects the fluid in a vapor form into stationary vacuum chamber 110 via gas inlet port 120. Chemical delivery system 122 can include multiple fluid sources 138 a-e, each of which can provide chemically different precursors, reactants, or inert gas for a treatment process. Although FIG. 3 illustrates five fluid sources, the use of fewer or more gas sources is contemplated. Chemical delivery system 122 can include a vaporizer 146 to convert the liquid to vapor immediately before the precursor or reactant enters a gas inlet 120. Vaporizer 146 can be immediately adjacent the outer wall of stationary vacuum chamber 110, e.g., secured to or housed adjacent to gas inlet port 120.

Comb 158 is affixed to shaft 156 and is retractable so that the tines of comb 158 can be moved out of the particle bed 148 and back into the path of particle motion as needed.

System 100 includes one or more motors 130a, 130b configured to provide torque that translates into rotary motion of one or more components of the system 100. Vessel motor 130a is coupled to rotary treatment vessel 112 and configured to provide torque that is translated into rotary motion of rotary treatment vessel 112 during operation of system 100. Comb motor 130b is coupled to a comb assembly 132 and configured to provide torque that is translated into rotary motion of comb assembly 132 (e.g., 180° rotation) during operation of system 100.

System 100 further includes a controller 170 that is operable to control the actions of chemical distribution system 122 and motors 130a, 130b. Controller 170 can be configured to operate the vessel motor 130a to generate a rotary motion of the rotary treatment vessel 112 in first direction 152 at a rotational speed of the rotary treatment vessel 112 suitable for each phase of the treatment process. At times during the treatment process, vessel motor 130a produces a rotational speed of the rotary treatment vessel 112 sufficiently high that particles 148 are centrifugally forced against inner surface 150 of the rotary treatment vessel 112. At other times during the treatment process, vessel motor 130a produces a rotational speed of rotary treatment vessel 112 that does not centrifugally force particles 148 against inner surface 150 of the rotary treatment vessel 112, but rather allows particles 148 to disengage from inner surface 150 of rotary treatment vessel 112.

A more detailed description of the rotary reaction system of FIG. 3 may be found in described in U.S. Provisional Application 63/312,851 filed on Feb. 23, 2022, and entitled Apparatus for Fine Powder Particle Processing Utilizing Centrifugal Confinement to Mitigate Particle Elutriation, the entire disclosure of which is incorporated herein by reference.

It should be understood that the systems 10 of FIGS. 1 and 2 may also include a chemical distribution system and controller similar to those described in connection with FIG. 3.

It should also be understood that the systems described above can be employed for chemical vapor deposition (CVD) processes to deposit materials onto a surface (e.g., onto any solid substrate), or for chemical vapor infiltration (CVI) processes to deposit materials onto and within any three-dimensional porous substrate (e.g., mesh structures). It is also contemplated that the systems described above can be employed for both CVD and CVI processes, such as, for example, where a CVD process is used to grow vertically aligned arrays of CNTs on a foil or other solid substrate, and then a CVI process is used to deposit materials between and amongst the vertically aligned arrays of CNTs that were formed in the same chemical vapor processing reactor.

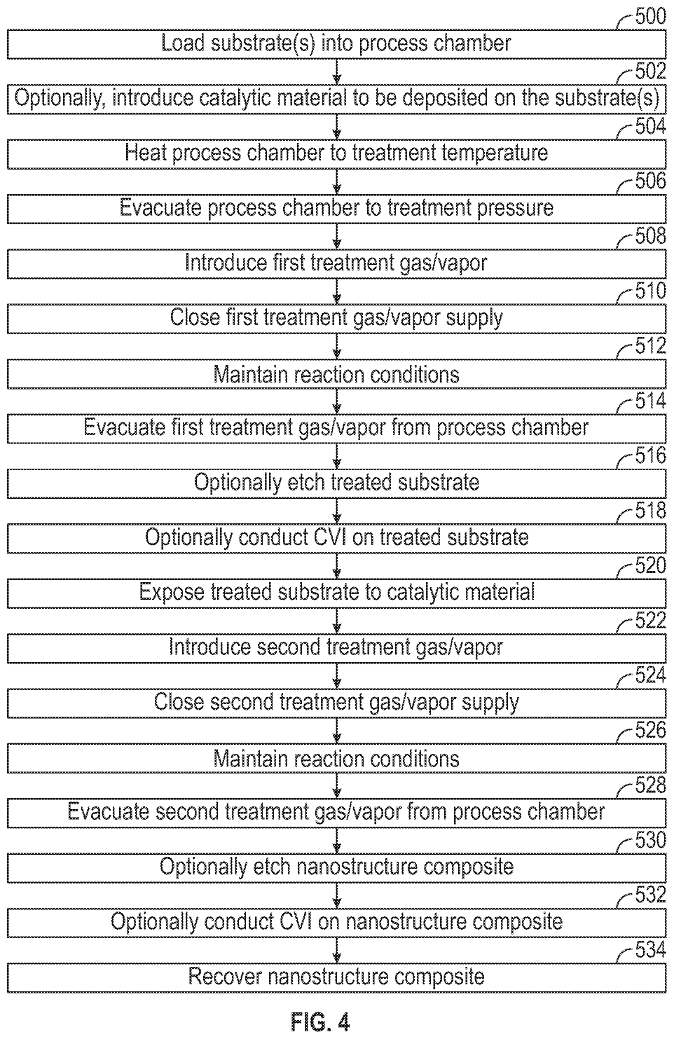

FIG. 4 is a flow chart showing an exemplary method for nanomaterial production in accordance with aspects of the present disclosure. As will be appreciated, some steps in the exemplary method may be performed manually and some steps in the exemplary method may be computer-implemented. In embodiments, however, some of the steps indicated to be performed manually may be automated and some of the computer-implemented steps may be performed manually. In addition, while the exemplary method of FIG. 4 illustrates a plurality of steps in a particular order, the steps need not all be performed in the same order as shown and may be performed in any suitable sequence and/or some steps may be omitted entirely.

Initially, one or more substrates (particulate, porous, or non-porous) to be treated are loaded into a process chamber at step 500. Examples of particulate materials on which nanomaterials may be deposited include C, Si, TiN, TiCN, TiC, ZrC, ZrN, VC, VN, cBN, Al₂O₃, Si₃N₄, SiB₆, W₂B₅, AlN, AlMgB₁₄, MoS₂, MOSi₂, Mo₂B₅, Mo₂B, diamond, or any fine powder or combination thereof. The particulate materials may have particles of any size, and in embodiments are fine, Group C particles. In addition, the particulate materials may include particles of any shape, including but not limited to generally spherical, fibers or plates. Examples of porous materials onto and/or within which nanomaterials may be deposited include any three-dimensional structure, including but not limited to mesh structures (e.g., metal meshes made, for example, of Ti, Ni, alloys, and the like), and bi-continuous tortuous phase structures such as carbon-infiltrated vertically aligned carbon nanotube (c-VACNT) structures described in International Application No. PCT/US20/49466 filed Sep. 4, 2020, the entire disclosure of which is incorporated herein by reference. Examples of non-porous materials onto which nanomaterials may be deposited include any solid structure, including but not limited to Si wafers and metal foil.

The substrate(s) may be catalytically active prior to insertion into the process chamber. That is, the substrate may be covered at least in part with a nanomaterial growth layer, such as, for example, gold (Au, copper, copper oxide, iron, or other catalytic material within the purview of one skilled in the art) in the form, e.g., of a film (typically on the order of nanometers to tens of nanometers), or as spatially isolated, randomly distributed nanoparticles. Alternatively, at step 502, the substrate within the process chamber may be exposed to catalytic material under conditions which will result in deposition of the catalytic material onto the substrate.

In embodiments, liquid catalyst precursors, (such as, for example, Cu(1,1,1,5,5,5-hexafluoroacetylacetonate)(vinyltrimethylsilane) (Cu(hfac)(tmvs)) to provide a copper catalyst for SiNW deposition or ferrocene (Fe(C₅H₅)₂) for CNT deposition), can be introduced into the process chamber under conditions which will result in deposition of a catalytic material onto the substrate. In embodiments where liquid catalyst injection is used, liquid catalyst may be introduced into the process chamber by a chemical distribution system 122 associated with the systems of FIGS. 1-3. In other embodiments, a separate liquid injector (not shown) may be inserted through the end cap 14 into the process tube 16. (See, FIGS. 1 and 2.) The length of the injector is chosen to have the tip of the nozzle to be between the end cap 14 (process tube inlet) and first furnace zone 32 to achieve a specific temperature between the room temperature and process temperature to evaporate the liquid into vapor. The liquid catalyst injector line, whether part of chemical distribution system 122 or a separate injector, may have an in-line vaporizer to inject hot vapor directly into the process chamber.

At step 504, the process chamber is heated to a desired treatment temperature. For example, in some cases treatment may be performed at a processing temperature above 50° C. (e.g., 50-1100° C.) or in other cases at a processing temperature below 50° C. (e.g., at or below 35° C.). In general, the particles can remain or be maintained at such temperatures.

At step 506, gas is exhausted from the process chamber to provide reduced pressure (i.e., at least a partial vacuum; e.g., pressures less than 1 Torr, e.g., 1 to 100 mTorr, in embodiments, 50 mTorr) within the process chamber.

At step 508, first treatment gas/vapor is introduced into the process chamber. In embodiments, the introduction of the first treatment gas/vapor raises the pressure within the process chamber to a pressure of 10 to 500 Torr; in embodiments to a pressure of 30 to 300 Torr; in embodiments to a pressure of 50 to 150 Torr. The first treatment gases/vapors may include, but are not limited to, helium, neon, argon, krypton, xenon, hydrogen, air, carbon monoxide, hydrogen bromide, hydrogen chloride, hydrogen fluoride, nitrogen, deuterium, oxygen, nitric oxide, hydrogen iodide, fluorine, chlorine, hydrogen sulfide, hydrogen selenide, carbon dioxide, nitrous oxide, methane, ammonia, phosphine, sulfur dioxide, methyl fluoride, carbonyl sulfide, arsine, cyanogen chloride, ethylene, silane, acetylene, germane, carbonyl fluoride, boron trifluoride, fluoroform, nitrogen trifluoride, ethane, diborane, phosgene, phosphorus trifluoride, carbon tetrafluoride, dichlorosilane, propylene, boron trichloride, perchloryl fluoride, chlorine trifluoride, dimethylamine, silicon tetrafluoride, propane, tetrafluoroethylene, disilane, germanium tetrafluoride, butene, silicon tetrachloride, trimethylamine, sulfur hexafluoride, isobutane, butane, hexafluoroethane, tungsten hexafluoride, perfluoropropane, octafluorocyclobutane, hexafluoropropylen, pentafluoroethane, difluoromethane, methylsilane, trimethylsilane, octafluorocyclopentene, hexafluoro-2-butyne, hexafluoro butadiene-1-3, epoxyperfluoro-cyclopentene, trisilylamine, dimethylethylamine, etc. The first treatment gases/vapors may also include vapors of metalorganic precursors such as trimethylaluminum, dimethylselenium, trimethyl-gallium, trimethylindium, molybdenum hexacarbonyl, etc. The first treatment gases/vapors may also include volatilized liquids such as water, tetraethyl orthosilicate, germanium tetrachloride, trichlorosilane, etc. The first treatment gases/vapors may also include vapors of sublimated solids such as borazine, molybdenum trioxide, etc.

The treatment gas/vapor supply is closed at step 510 and the treatment conditions with the first treatment gas/vapor are maintained for a desired treatment time at step 512 in order to deplete the reactants. In embodiments, this step is primarily a dwell step to allow the desired treatment to take place and typically involves no introduction of treatment gas/vapor, although for some embodiments a continuous flow of treatment gas/vapor may be employed.

Once the desired treatment is achieved, at step 514 the first treatment gases/vapors are pumped out of the process chamber.

The present method may, in embodiments, result in chemical vapor deposition (CVD) of carbon nanotubes (CNTs) on the substrates. CVD deposition allows to achieve multiwall vertically aligned CNTs (VACNT) with a length of several tens of micrometers to several millimeters and typical diameter of several tens of nanometers. Such VACNTs are very fragile and tend to break easily if removed from the substrate. At step 516, an optional etching step can be used to prepare the treated substrate prior to an optional carbon chemical vapor infiltration (CVI) process (step 518) that can be used to bond VACNTs with carbon into more robust mechanically rigid structures that can later be removed from the substrate and remain mechanically stable. Such structures can be free standing and formed into sheets or milled into a powder to form nano-porous carbon particles.

At step 520, the treated substrate (now having the nanomaterials from the first exposure to treatment gas/vapor and optionally stabilized by a CVI process) may be exposed while still within the same process chamber to the same or a different catalytic material under conditions which will result in deposition of the catalytic material onto the previously treated substrate. The catalytic material used in this step should be chosen to initiate and encourage deposition of whatever additional nanomaterials are to be deposited in subsequent steps. It is contemplated that where, for example, CNTs are formed by exposure to the first treatment gas/vapor, and SiNW are to be formed by exposure to the second treatment gas/vapor, a common catalytic material may be chosen suitable for growth of both CNTs and SiNWs. Several metals, for example, Cu, Ni, Al and others can be used as catalyst for deposition of both CNTs and SiNW under different or similar process conditions. Sequential deposition of SiNW and CNT can be achieved, for example, by injection of Si-containing precursors for SiNW deposition followed by C-containing precursors for CNT deposition. Alternatively, nanoparticles of another catalyst material can be used for silicon nanowire (SiNW) growth via vapor-liquid-solid (VLS) CVD deposition on and inside a porous carbon structure previously prepared in the process chamber.

In other embodiments, with proper tuning of the process conditions, CNT and SiNW can be deposited simultaneously within a single process chamber at the temperature range between 500 and 900 degrees Celsius and process pressure ranging from approximately 0.1 Torr to approximately 100 Torr. Simultaneous deposition may be achieved by concurrent injection of the precursors for CNT deposition, such as, for example, acetylene (C₂H₂) or ethylene (C₂H₄), and the precursors for the SiNW deposition, such as, for example, silane (SiH₄) or disilane (Si₂H₆). Co-deposited networks of SiNW and CNT can be further infiltrated with carbon using CVI process parameters within the same process chamber to enable SiNW encapsulation inside carbon-based structure.

At step 522, second treatment gas/vapor is introduced into the process chamber to deposit nanomaterial onto/within the catalytically activated treated substrate while still within the same process chamber. In embodiments, the introduction of the second treatment gas/vapor raises the pressure the process chamber to a pressure of 10 to 500 Torr; in embodiments to a pressure of 30 to 300 Torr; in embodiments to a pressure of 50 to 150 Torr. In other embodiments (e.g., where the second treatment gases/vapors are chosen to produce SiNW deposition), the introduction of the second treatment gas/vapor raises the pressure the process chamber to a pressure of 750 to 7500 Torr; in embodiments to a pressure of 1000 to 3000 Torr. The second treatment gases/vapors may include, but are not limited to, any of the materials identified above with respect to the first treatment gas/vapor. The result of this step is what is referred to herein as a nanomaterial composite.

The treatment gas/vapor supply is closed at step 524 and the treatment conditions with the second treatment gas/vapor are maintained for a desired treatment time at step 526 in order to deplete the reactants. Once the desired treatment is achieved, at step 528 the second treatment gases/vapors are pumped out of the process chamber.

Where the nanomaterial composite is a porous material, at step 532, an optional chemical vapor infiltration (CVI) process can be performed. For example, where exposure to the first treatment gas/vapor produces CNTs on the substrate, and exposure to the second treatment gas/vapor results in deposition of the SiNW, carbon CVI of the resulting nanomaterial composite may be used to encapsulate SiNW with carbon while leaving substantial void space inside of the resulting composite structure. This CVI method can alternatively be used to infiltrate porous carbon structures with silicon thereby forming nanosilicon clusters inside the porous graphite. An optional etching step (530) can be used to remove metal catalyst residue prior to carbon CVI encapsulation. Such an etching step may be beneficial where the resulting nanomaterial composite that may negatively impact battery performance with such nanostructure composite silicon carbon material.

At step 534, the nanostructure composite is recovered from the process chamber. Those skilled in the art reading this disclosure will readily envision ways to recover nanostructure composite from the process chamber of the systems shown in any of FIGS. 1-3.

Based on the above teachings, those skilled in the art will appreciate that the methods described herein can be beneficial for forming nanosilicon-containing nanocarbon structures suitable for use as a battery anode material.

It should be understood that the foregoing description is only illustrative of the present disclosure. Various alternatives and modifications can be devised by those skilled in the art without departing from the disclosure. Accordingly, the present disclosure is intended to embrace all such alternatives, modifications and variances. The embodiments described with reference to the attached drawing figures are presented only to demonstrate certain examples of the disclosure. Other elements, steps, methods, and techniques that are insubstantially different from those described above and/or in the appended claims are also intended to be within the scope of the disclosure.

What is claimed is:

1. A method for growing nanomaterials comprising:
loading a catalytically active substrate into a process chamber;
introducing first treatment gases/vapors into the process chamber to make a treated substrate;
depositing catalytic materials on the treated substrate while it remains in the process chamber; and
exposing the catalytically activated treated substrate to second treatment gases/vapors to create a nanostructure composite.

2. The method of claim 1, further comprising etching at least one of the treated substrate or the nanostructure composite.

3. The method of claim 1, further comprising CVI treating at least one of the treated substrate or the nanostructure composite.

4. The method of claim 1, wherein loading a catalytically active substrate into a process chamber comprises loading a particulate, porous, or non-porous catalytically active substrate into the process chamber.

5. The method of claim 1, wherein the treated substrate may be vertically aligned carbon nanotube (VACNT) structures.

6. The method of claim 1, wherein the nanostructure composite includes CNTs and SINWs.

7. The method of claim 1, wherein the nanostructure composite is suitable for use in making a battery anode.

8. A method comprising:
depositing, via chemical vapor deposition (CVD), carbon nanotubes (CNTs) on a substrate having a first metal or metal oxide catalyst layer to provide a CNT-containing substrate;
depositing a second metal or metal oxide catalyst layer suitable for SiNW deposition onto the CNT-containing substrate to provide a catalytically active CNT-containing substrate;
depositing, via CVD, SiNW onto the catalytically active CNT-containing substrate to provide a SiNW-coated catalytically active CNT-containing substrate; and
at least partially encapsulating, via chemical vapor infiltration, the SiNW-coated catalytically active CNT-containing substrate with carbon to provide a composite structure having substantial void space therein.

9. The method of claim 8, further comprising etching the CNT-containing substrate prior to depositing SiNW.

10. The method of claim 9, wherein etching is chemical or plasma assisted etching.

11. The method of claim 8, further comprising etching the SiNW-coated catalytically active CNT-containing substrate prior to the encapsulating.

12. A method comprising:
depositing at least one of SiNW or CNT onto a substrate using one or more liquid catalyst precursors,
wherein the liquid catalyst precursor is copper catalyst for SiNW deposition, and
wherein the liquid catalyst precursor is ferrocene (Fe(C₅H₅)₂) for CNT deposition.

13. The method of claim 12, wherein the liquid catalyst precursor is Cu(1,1,1,5,5,5-hexafluoroacetylacetonate) (vinyltrimethyl-silane) (Cu(hfac)(tmvs)).

14. A method comprising:
positioning a substrate within a single process chamber; and
depositing a metal-based or metal oxide-based catalyst layer onto the substrate while the substrate is within the process chamber, the catalyst layer suitable for chemical vapor deposition (CVD) of carbon nanotubes (CNTs), SiNW, or both.

15. The method of claim 14, further comprising depositing CNTs and SiNW simultaneously or sequentially while the substrate remains within the process chamber in which the catalyst layer was deposited.

16. The method of claim 14, wherein the oxide-based catalyst layer comprises Cu, Ni, or Al.

17. The method of claim 14, wherein depositing the catalyst layer onto the substrate is conducted at a temperature from 500 and 900 degrees Celsius.

18. The method of claim 14, wherein depositing the catalyst layer onto the substrate is conducted at a pressure from 0.1 Torr to 100 Torr.

19. The method of claim 15, further comprising at least partially encapsulating, via chemical vapor infiltration, the SiNW- and CNT-containing substrate with carbon to provide a composite structure having substantial void space therein.
